(19) United States
(12) Patent Application Publication
(10) Pub. No.: US 2004/0057216 A1
(43) Pub. Date: Mar. 25, 2004

(54) Electronic component rack assembly and method

(76) Inventors: John V. Smith, Poway, CA (US); Victor P. Hester, El Cajon, CA (US); Greg F. Miller, San Diego, CA (US)

Correspondence Address: DUCKOR SPRADLING METZGER, 401 WEST A STREET, SUITE 2400, SAN DIEGO, CA, 92101-7915, US

(21) Appl. No.: 10/658,440

(22) Filed: Sep. 8, 2003

Related U.S. Application Data
(60) Provisional application No. 60/413,922, filed on Sep. 25, 2002.

(51) Int. Cl. H05K 5/00

(52) U.S. Cl. 361/724

(57) ABSTRACT

According to at least one of the disclosed embodiments of the present invention, there is provided a rack mounted system employing vertically mounted electronic components in the form of blades for supporting circuit devices such as computer components. The blades are mounted in a series of vertically spaced apart bays. In one example of the invention, in each bay, the vertically mounted blades are interconnected to a power distribution unit strip to cause the blades to be mounted compactly. In one example, a pair of sets of vertically mounted blades are attached to opposite sides of the power distribution unit in a back-to-back configuration within the same bay.

### RELATED APPLICATION

This application claims priority to U.S. provisional patent application Serial No. 60/413,803, titled “Method and Apparatus for Rack Mounting Computer Components,” filed Sep. 25, 2002, which is hereby incorporated by reference in its entirety. Additionally, priority is claimed to U.S. non-provisional patent application Ser. No. 10/449,799, filed May 29, 2003, titled “Rack Mountable Computer Component and Method of Making Same”; Ser. No. 10/448,691, filed May 29, 2003, titled “Rack Mountable Computer Component Cooling Method and Device”; Ser. No. 10/449,608, filed May 29, 2003, titled “Rack Mountable Computer Component For Cooling Arrangement and Method; and Ser. No. 10/448,508, filed May 29, 2003, titled “Rack Mountable Computer Component Power Distribution Unit and Method”.

This application is related to U.S. patent Ser. No. 10/160,526, titled “Method and Apparatus for Rack Mounting Computer Components” filed May 31, 2002, and U.S. provisional application Serial No. 60/384,996, titled “Rack Mountable Computer Component and Method of Making Same”, filed May 31, 2002; U.S. provisional application Serial No. 60/384,987, titled “Rack Mountable Computer Component Cooling Method and Device”, filed May 31, 2002; U.S. provisional application Serial No. 60/384,986, titled “Rack Mountable Computer Component Fan Cooling Arrangement and Method”, and U.S. provisional application Serial No. 60/385,005, titled “Rack Mountable Computer Component Power Distribution Unit and Method”, which are each hereby incorporated by reference in their entirety.

### BACKGROUND OF THE INVENTION

1. Field of the Invention

The present invention relates in general to a new and improved method and apparatus for rack mounting electronic components. It more particularly relates to such a method and apparatus for rack mounting electronic components such as computer components in a compact configuration.

2. Related Art

There have been a variety of different types and kinds of methods and systems for mounting computer components. For example, reference may be made to the following United States patents, each of which is incorporated herein by reference in its entirety:

| PATENT NO. | INVENTOR | ISSUE DATE |
|---|---|---|
| 4,258,967 | Boudreau | Mar. 31, 1081 |
| 4,879,634 | Storrow et al. | Nov. 7, 1989 |
| 4,977,532 | Borkowicz et al. | Dec. 11, 1990 |
| 5,010,444 | Storrow et al. | Apr. 23, 1991 |
| 5,216,579 | Basara et al. | Jun. 1, 1993 |
| 5,460,441 | Hastings et al. | Oct. 24, 1995 |
| 5,571,256 | Good et al. | Nov. 5, 1996 |
| 5,684,671 | Hobbs et al. | Nov. 4, 1997 |
| 5,877,938 | Hobbs et al. | Mar. 2, 1999 |
| 5,896,273 | Varghese et al. | Apr. 30, 1999 |
| 6,025,989 | Ayd et al. | Feb. 15, 2000 |
| 6,058,025 | Ecker et al. | May 2, 2000 |
| 6,075,698 | Hogan et al. | Jun. 13, 2000 |
| 6,220,456 B1 | Jensen et al. | Apr. 24, 2001 |
| 6,305,556 B1 | Mayer | Oct. 23, 2001 |
| 6,315,249 B1 | Jensen et al. | Nov. 13, 2001 |
| 6,325,636 B1 | Hipp et al. | Dec. 4, 2001 |
| Re. 35,915 | Hastings et al. | Oct. 6, 1998 |
| Des. 407,358 | Belanger et al. | Mar. 30, 1999 |

As a result of having available a large number of different types and kinds of mounting techniques, a standard has been adopted for mounting computer components in racks according to a certain modular configuration. In this regard, computer components such as computer processor units, and the like, are mounted horizontally one above the other in a column in standard size rack configurations. The standard is referred to as the EIA-310-D Standard, as clarified by the Server Rack Specification (SSI).

The housing for each computer device must have a certain height dimensions according to the Standard. The height dimension must be a multiple of a standard unit “U”. Thus, there can be computer components which are 1 “U” (standard unit) high or multiples thereof. Thus, there can also be standard rack mountable computer components which are 1 U, 2 U, 3 U, 4 U and so on.

Thus, according to the conventional currently-used standard, racks are provided for storage of computer components in tightly spaced, densely packed horizontal dispositions, and each computer component mounted in the rack is suitably dimensioned in multiples of standard unit U. The racks are movably mounted on casters or the like so that they can be readily positioned in, for example, a computer room having a tightly controlled air conditioning system to ensure proper cooling of the computer equipment.

It is highly desirable to configure the computer components in the rack in a compact and highly dense manner for some applications. Thus, it has been important for many applications to position in the computer room or other assigned space as many computer components as possible.

In order to compactly mount the computer components on the rack in a high density manner, they are closely positioned one above the other in a column. The data and power cables are positioned in a back plane area or space within the rack.

For cooling purposes, various techniques are employed. For example, individual fans have been mounted within the housing of each computer component. The interiors of the housing have been exhausted to a fan exhaust plenum chamber often times constructed within the rack at one side thereof.

Such conventional rack mounted systems have several drawbacks. The individual fans mounted in each component are expensive, and time-consuming to replace in case of malfunctions. Also, the back plane space and fan exhaust plenum chamber are wasted space in that they occupy spaces which could otherwise be filled with computer components.

Additionally, in order to assemble the rack mounted system for installation at the site, each component must be installed in place within the rack, and then the cabling for each unit is routed within the rack at its back plane space. Such an operation is time consuming, and therefore expensive since highly trained personnel are required to do such an installation. Furthermore, once installed, in order to replace a malfunctioning computer component, the entire system, or at least a substantial portion thereof, must be shut down so that the malfunctioning unit can be disassembled, and a replacement unit installed and reconnected electrically. This, too, is time consuming and expensive.

### BRIEF DESCRIPTION OF THE DRAWINGS

The following is a brief description of the drawings:

FIG. 1 is a pictorial view of a rack-mounted assembly showing the front, left side and top thereof, which is constructed in accordance with an embodiment of the present invention;

FIG. 2 is a pictorial view of a housing illustrating the process of installation of blades;

FIG. 3 is an enlarged scale top view of one embodiment of a blade of the rack-mounted assembly of FIG. 1;

FIG. 4 is a left side elevational view of the blade of FIG. 3;

FIG. 5 is a side view of another embodiment of a vertically mountable blade;

FIG. 6 is a front view of the blade of FIG. 5;

FIG. 7 is a top view of the blade of FIGS. 5 and 6;

FIG. 8 is a fragmentary front elevational diagrammatic view of the assembly of FIG. 1;

FIG. 9 is a fragmentary side elevational diagrammatic view of the assembly of FIG. 8; and

FIG. 10 is a fragmentary diagrammatic sectional plan view of the assembly of FIG. 1 shown resting on a computer room ventilated floor.

### DESCRIPTION OF CERTAIN EMBODIMENTS OF THE INVENTION

According to at least one of the disclosed embodiments of the present invention, there is provided a rack mounted system employing vertically mounted electronic components in the form of blades for supporting circuit devices such as computer components. The blades are mounted in a series of vertically spaced apart bays. In one example of the invention, in each bay, the vertically mounted blades are interconnected to a power distribution unit strip to cause the blades to be mounted compactly. In one example, a pair of sets of vertically mounted blades are attached to opposite sides of the power distribution unit in a back-to-back configuration within the same bay. The dimensions are critical to achieve the desired compact high density spacing.

According to certain embodiments of the invention, there is provided an electronic component rack assembly including a rack having width Wr, where Wr is equal to about 24 inches. A group of N number of electronic components are mounted side-by-side upright in a series of spaced-apart vertical planes on the rack housing. Each component is spaced apart by a distance Wb, where Wb is equal to about 1.93 inches. N is an integer number equal to either 11 or 12.

According to other examples of the disclosed invention, another group of N number of electronic components are mounted side-by-side upright in a series of spaced-apart vertical planes on the rack housing opposite to the first-mentioned group of components in a back-to-back registration. In one embodiment, a power distribution unit extends transversely to the vertical planes between the first-mentioned and second electronic components to provide electrical power thereto. According to the disclosed embodiment of the invention, each one of the first-mentioned and the second electronic components has a depth Db, and the unit has a thickness t. The depth of the rack housing is Dr, and is equal to 2 Db(t).

In the disclosed embodiments, the blades may be sized to make efficient use of the rack bays. A blade may have a width such that an integer multiple of the width is approximately equal to the width of the bay. In one embodiment, the width of the blade is about 1.93 inches. In another embodiment, the width is approximately one-eleventh the width of a rack bay.

In the disclosed embodiments, the height of a board region of a vertically mountable blade is twice the length of one dimension of a selected motherboard mounted on said board region. In one embodiment, the height is about 19.33 inches.

General System Description

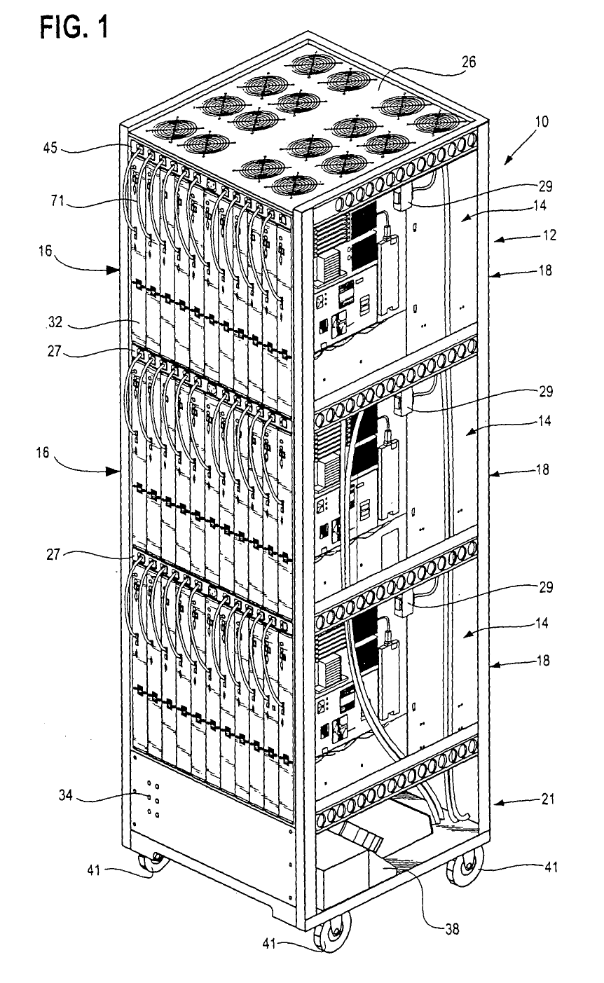

Referring now to FIGS. 1 through 4, there is illustrated one embodiment of a rack mounted system or assembly 10 according to the present invention. The rack mounted system 10 includes a rack housing 12 configured generally as a rectangular box having a plurality of vertical bays 14. The embodiment illustrated in the drawings includes three vertically spaced-apart bays 14.

Each bay 14 is divided into a front bay portion 16 and a rear bay portion 18 by an intermediate transversely-extending horizontal divider 19. The bays 14 are formed in the rack housing 12 in a vertical manner one above the other. In a bottom portion of the rack housing 12, a control bay 21 is provided to house various controlled components, as hereinafter described in greater detail.

The rack housing 12 further includes a fan/LAN tray slot 23 above each bay 14. Each fan/LAN tray slot is configured to accommodate a fan/LAN tray such as tray 27.

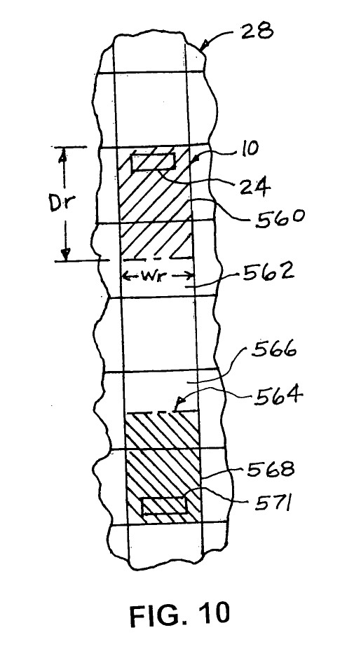

As best seen in FIG. 10, the embodiment illustrated in the drawings provides a control bay 21 having a bottom opening 25 for facilitating air flow to receive vertically moving air flow from a vent opening 24 in a floor 28 and vertically through the system 10 as assisted by the fan/LAN trays. At the top of the rack housing 12, an apertured top panel 26 is provided to permit venting of the vertically moving air flow from the system 10.

At the top portion of each bay 14, in the intermediate region between the front bay portion 16 and the rear bay portion 18, a power distribution unit (PDU) 29 is provided to supply electricity to various components mounted in the rack mounted system. Each bay is adapted to accommodate a plurality of computer components in the form of open structure computer blades, such as blade 32, in each of the front bay portions 16 and the rear bay portions 18. In the embodiment illustrated in the figures, eleven blades may be accommodated in each of the front bay and rear bay portions. Thus, in the illustrated embodiment, the system 10 accommodates 66 computer components in a densely compact, closely spaced configuration.

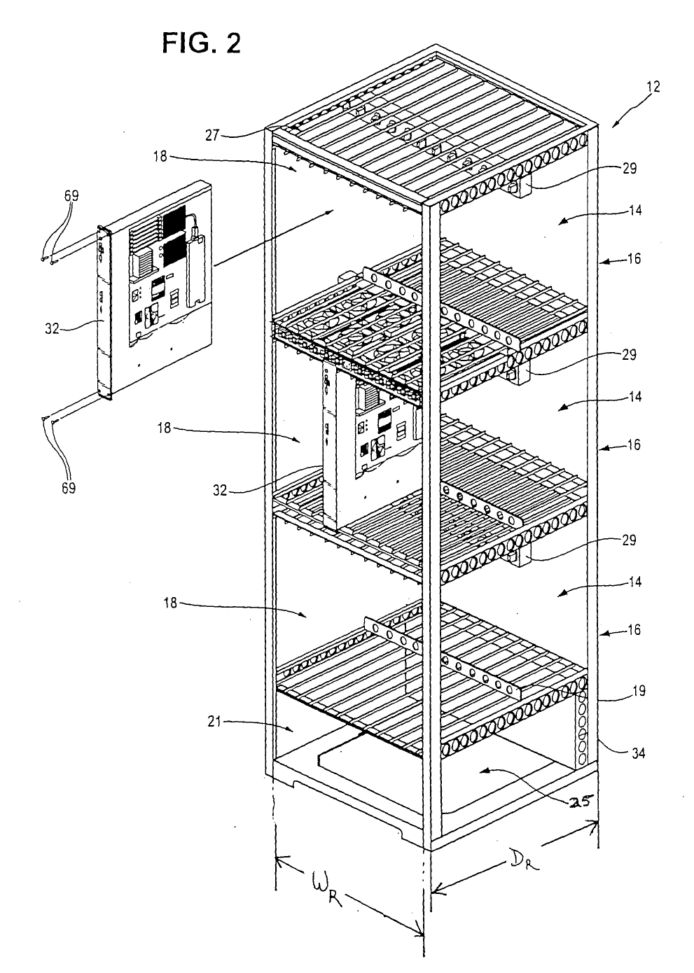

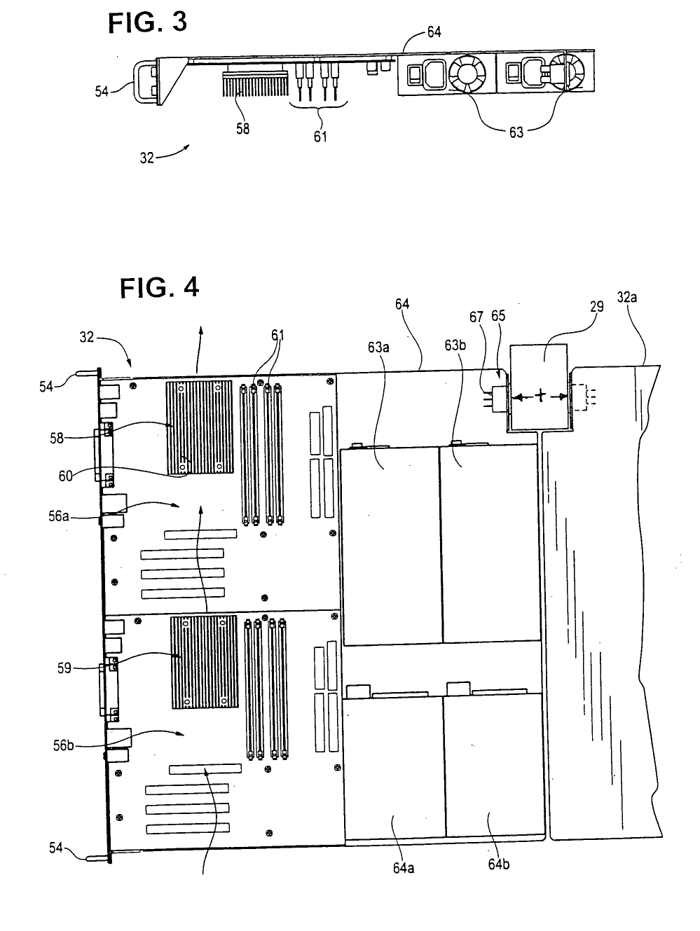

Referring now to FIGS. 2-4, the blades 32 and their installation into the rack housing 12 will now be described in greater detail. Each blade is provided with a pair of handles 54 which allow a user to easily manipulate the blade 32 to be grasped by the user to slide the blade into or out of its bay. Each blade 32 may include one or more mother boards 56. In the embodiment illustrated in FIGS. 3 and 4, each blade 32 includes two mother boards 56a, 56b. Those skilled in the art will appreciate that the number of mother boards included in each blade 32 may be varied according to design. The mother board may include heat sinks such as heat sinks 58 and 59 for facilitating the cooling of the mother boards. Embodiments of the heat sinks are disclosed in greater detail in U.S. provisional attorney docket no. 035374-2003, filed May 31, 2002. Further, each mother board is provided with random access memory (RAM) 61. The amount of RAM 61 provided for each mother board may be varied as needed. A pair of power supply 63a, 63b may be provided on the blade 32 for supplying power to their corresponding mother boards 56a, 56b. Similarly, a pair of hard disks 64a, 64b may also be provided on the blade 32.

All of the components are mounted on one side of a rigid plate or support 64, which is adapted to be supported vertically within its bay. Each blade 32 includes a cut-out corner portion or section 65 in its upper back portion. The cut-out portion 65 is sized to receive and accommodate the PDU 29 therebetween such that two opposing blades 32 and 32a accommodate the PDU 29 almost completely. Thus, a substantially zero footprint is achieved for the PDU 29. Each blade 32 is provided with an AC power inlet such as an inlet 67 at or near the cut-out portion 65. Thus, when the blade 32 is installed into the rack housing 12, the AC power inlet 67 engages electrically a corresponding AC connector such as a connector 76 of the PDU 29.

As most clearly illustrated in FIG. 2, the installation of the blade 32 may be achieved in a fast and efficient manner. The blade 32 is simply slid into either the front bay portion 16 or the rear bay portion 18 of a bay 14 of the rack housing 12. Each blade 32 is slid back until its AC power inlet 67 engages a corresponding AC connector 76 on the PDU 29. The intermediate dividers 19 serve as a back stop for the blades 32. Each blade 32 is secured in its slot by four blade screws 69, which attach the blade 32 to the rack housing 12.

Once the blade 32 has been mounted onto the rack housing 12, a short blade/LAN connector cable such as a cable 71 provides electrical networking connection between the blade 32 and a network such as a local area network, wide area network or a public network such as the internet. In this regard, the mother boards are each mounted at the front of each blade, and thus access thereto is readily available at front outlets.

Compact Mounting Arrangement

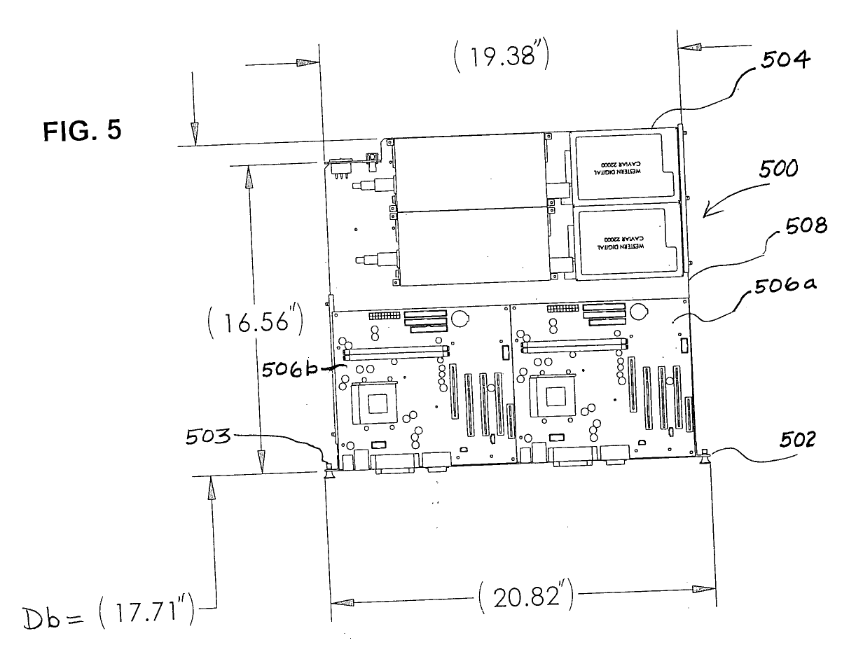

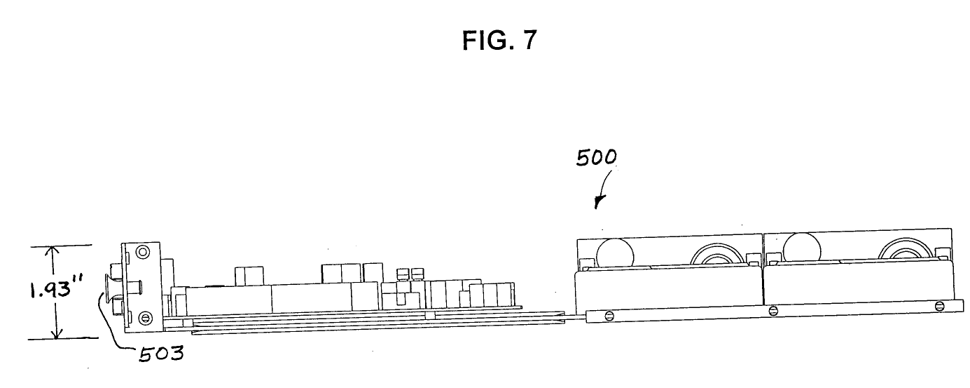

In order to compactly configure the system, a blade may be configured to maximize or at least greatly increase the density of the electronic components in the rack assembly, the number of components that may be housed in the system. FIGS. 5-7 illustrate one embodiment of a blade 500 sized to maximize or increase the density of the number of such blades that may be accommodated in a rack housing such as the rack housing 12 illustrated in FIG. 1.

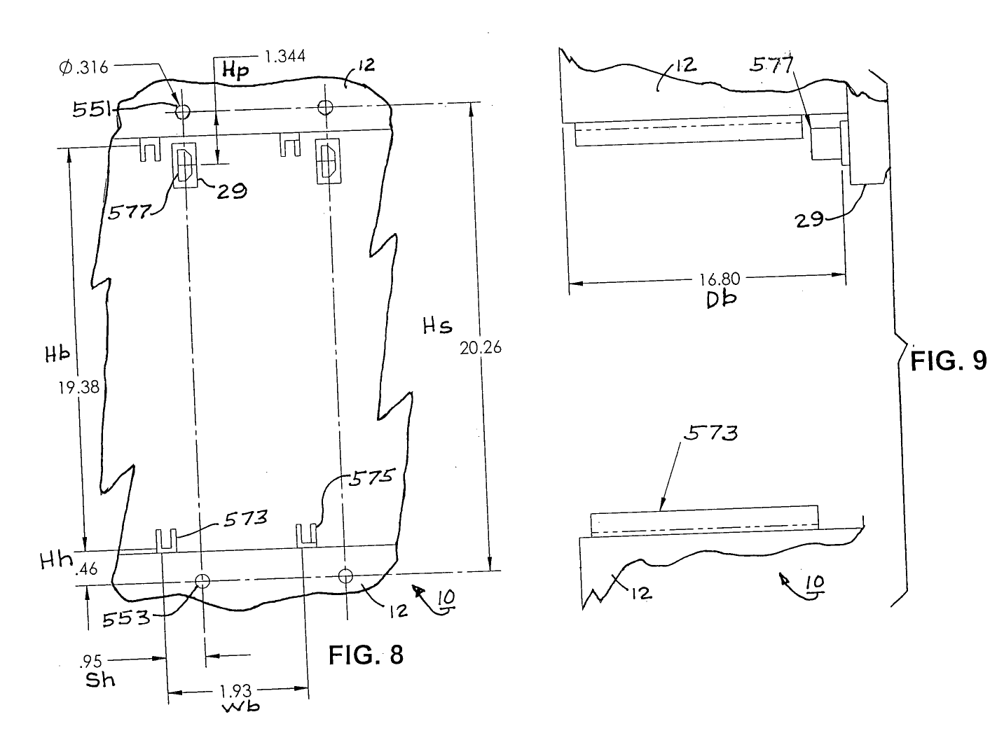

The vertically mountable blade 500 of FIGS. 5-7 is shown as having a height of 20.82 inches on the mounting frame between a pair of lower and upper snap latches 502 and 503, and 19.33 inches for the height of the board 504. The snap latches connect releaseably to the rack housing 12 by interengaging with a pair of upper and lower holes, such as an upper hole 551 and a lower hole 553 in the rack housing 12 as shown in FIG. 8. In order to make efficient use of the space in the bays, the height of the board is preferably minimized. In this regard, the height may be dictated by two adjacently mounted mother boards 506a, 506b. In one embodiment, the height of the blade 500 may be designed to be twice the size of the smallest available mother board.

Thus, a rack housing may be provided with several vertically spaced bays, each bay adapted to accommodate a set of vertically mounted blades. The number of bays may be limited by such considerations as the desire to maintain a maximum rack housing height such that the rack housing may be moved through a standard doorway.

Referring again to FIGS. 5-7, the depth, Db, of the illustrated blade is 17.71 inches along a horizontal edge 508. With two sets of blades mounted in back-to-back bays, as illustrated in FIG. 1, the depth of the rack housing, Dr, may be determined to be approximately double that of Db. In other embodiments, the depth of the rack, Dr, housing may be designed according to other considerations, such as the U standard. The blades may be designed accordingly.

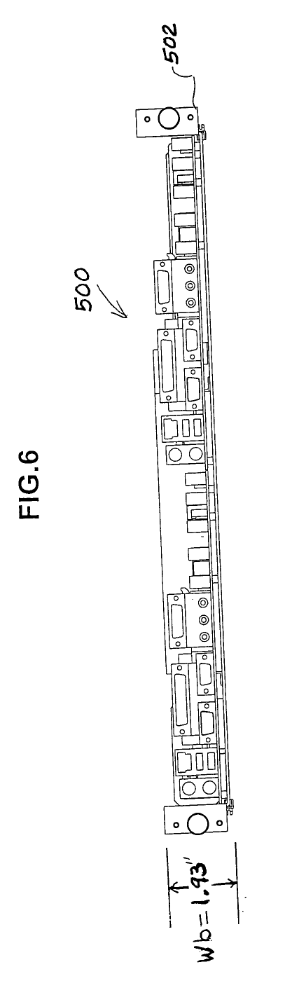

Referring now to FIGS. 6, 7, 8 and 9, the width of the illustrated vertically mountable blade 500, Wb, is shown as 1.93 inches. The width may be a critical dimension of the blade 500. Generally, a rack housing may comply with existing standards and may be limited to a particular width, Wr (FIG. 2), such as between about 21 inches and about 24 inches. Thus, the width of the blade 500 is preferably sized to make efficient use of this space. The width of the blade should be as small as possible in order to maximize the number of blades that may be mounted in the bay. On the other hand, the width of the electronic component blade should be large enough to accommodate the various components mounted thereon, such as the motherboard, power supply, etc.

Further, Wb is preferably selected such that a plurality of such blades may be mounted side-by-side, as illustrated in FIG. 1, and completely occupy the width of the rack housing, Wr. In the embodiment illustrated in FIG. 1, eleven blades are mounted side-by-side. However, it is to be understood that a different integer number N such as 12 may also be employed. With a blade having a width Wb of 1.93 inches, the rack housing can accommodate eleven side-by-side blades and have a rack width, Wr, of preferably approximately 24 inches. In one embodiment, the ratio of the widths, Wr/Wb, is approximately an integer value. In further embodiments, the integer value N may be eleven or twelve.

Thus, the space in the bays of the rack housing may be completely filled by designing a blade having a width that is approximately an exact factor of the width of the bay of the rack housing.

As shown in FIG. 10, the rack assembly 10 is adapted to rest on the computer room floor 28 above an air vent such as the vent 24 and be conveniently aligned with floor tiles, such as tiles 560 and 562. The tile 560 contains the floor vent 24. Each tile is conventionally square in shape and 24 inches by 24 inches.

The width Wr of the rack assembly 10 is the same width as the floor tiles, such as the tiles 560 and 562. The depth Dr of the rack assembly 10 is equal to the length of about one and one-half tiles. Thus, Dr is equal to between about 36 inches and about 38 inches.

Another rack assembly 564 may rest on tiles 566 and 568 over a vent 571 in the tile 568. Thus, the assemblies 10 and 564 are spaced apart by about two tile widths or 48 inches for convenient passage for the users of the rack assemblies.

As shown in FIGS. 8 and 9, a blade width spacing is preferably 1.93 inches between adjacent guides 573 and 575 for supporting a blade peripheral edge. The blade height Hb is 19.38 inches. As shown in FIGS. 8 and 9, the blade depth Db is 16.8 inches between an outlet 577 of the power distribution unit 29 and the entrance to the bay. The PDU 29 has a series of N number of spaced-apart outlets, such as the outlet 577. The height Hp of the hole or opening such as the hole 551 relative to the PDU 29 is 1.344 inches where the hole 551 is in vertical alignment with the PDU 29. The horizontal spacing Sh of the hole such as the hole 553 relative to its adjacent glide is preferably 0.95 inch. The hole height Hh of the lower hole 553 relative to the glide is 0.46 inch. The hole spacing Hs between upper and lower holes 551 and 553 is 20.26 inches. As seen in FIG. 4, the power distribution unit 29 has a thickness t, and the depth Db of a blade is shown in FIG. 9 as being 16.8 inches. Thus, the depth of the rack housing 12 is Dr (FIG. 2) and is equal to 2 Db(t).

While particular embodiments of the present invention have been disclosed, it is to be understood that various different modifications and combinations are possible and are contemplated within the true spirit and scope of the invention. There is no intention, therefore, of limitations to the exact disclosure herein presented.

What is claimed is:

1. An electronic component rack assembly, comprising:
a rack housing having a width Wr, where Wr is equal to about 24 inches;
a group of N number of electronic components mounted side-by-side, upright in a series of spaced-apart vertical planes on the rack housing;
said components being spaced apart by a distance Wb, where Wb is equal to about 1.93 inches, and where N is an integer number equal to either 11 or 12.

2. An electronic component rack assembly according to claim 1, further including another group of N number of electronic components mounted side-by-side upright in a series of spaced-apart vertical planes on the rack housing opposite to the first-mentioned group of components in a back-to-back registration;
a power distribution unit extending transversely to said vertical planes between the first-mentioned and second electronic components to provide electrical power thereto;
wherein each one of the first-mentioned and said second electronic components has a depth Db, and said unit has thickness t; and
wherein the depth of the rack housing is Dr, where Dr is equal to 2 Db(t).

3. An electronic component rack assembly according to claim 2, wherein each of said electronic components has a height equal to Hb, where Hb is equal to about 19.38 inches.

4. An electronic component rack assembly according to claim 3, wherein said rack housing includes a series of pairs of upper and lower component guides, said guides being spaced apart by a distance Wb.

5. An electronic component rack assembly according to claim 1, further including a power distribution unit extending transversely to said vertical planes at the rear of said electronic components, said unit having a series of N number of spaced-apart outlets for supplying electrical power to individual ones of the electronic components, each of said outlets being spaced from a holder for its electronic component by a distance s.

6. An electronic component rack assembly according to claim 5, wherein said rack includes a series of pairs of vertically spaced-apart latch openings for helping to secure said components releaseably to said rack, each one of said pairs of openings being disposed in vertical alignment with an outlet.

7. An assembly according to claim 1, wherein the depth Db of said electronic component is 16.8 inches.

8. An assembly according to claim 6, wherein the upper one of said openings is located at a height Hp relative to said unit outlet equal to 1.344 inches.

9. An assembly according to claim 6, wherein said openings are spaced horizontally from guides by a spacing Sh equal to 0.95 inch.

10. An assembly according to claim 6, wherein the lower one of said openings is located at a height Hh equal to 0.46 inch.

11. An assembly according to claim 1, wherein the depth of the assembly is between about 36 inches and about 38 inches.

12. A method of making an electronic component rack assembly, comprising providing a rack assembly according to the dimensions according to claim 1.
